(19) United States
(12) Patent Application Publication
(10) Pub. No.: US 2011/0012229 A1
(43) Pub. Date: Jan. 20, 2011

(54) SEMICONDUCTOR DEVICE WITH CAPACITOR AND METHOD OF FABRICATING THE SAME

(75) Inventor: CHUN-CHEN HSU, Taoyuan County (TW)

Correspondence Address: J C PATENTS, 4 VENTURE, SUITE 250, IRVINE, CA, 92618, US

(73) Assignee: United Microelectronics Corp., Hsinchu (TW)

(21) Appl. No.: 12/502,364

(22) Filed: Jul. 14, 2009

(51) Int. Cl. H01L 29/92; H01G 4/228; H01L 21/02

(52) U.S. Cl. 257/532; 361/306.1; 438/396; 257/E29.343; 257/E21.008

(57) ABSTRACT

A capacitor, comprising a substrate, a first electrode and a second electrode is provided. The first electrode is located over a substrate. The second electrode is located over the first electrode and overlapping with a portion of the first electrode. The dielectric layer is located between the first electrode and the second electrode and a portion of the first electrode, a portion of the dielectric layer and a portion of the second electrode, which overlap each other, are together form the capacitor. The first electrode is electrically connected to a first metal interconnects, the second electrode is electrically connected to a second metal interconnects underneath the second electrode and no via for being electrically connected to the second electrode is located over the second electrode.

### BACKGROUND OF THE INVENTION

1. Field of Invention

The present invention relates to an integrated circuit and a method for fabricating thereof. More particularly, the present invention relates to a semiconductor device with a capacitor and a method for fabricating thereof.

2. Description of Related Art

With the decreasing of the size of the semiconductor device, the space above the transistor is not only used to for arranging the metal interconnects but also used for disposing the device elements in order to decrease the area occupied by the device elements. Therefore, the some technical reports have proposed the arrangement in which the metal-insulator-metal capacitor is disposed over the transistor. However, the voltage is applied onto the top electrode and the bottom electrode of the typical transistor through the vias over the top electrode and the bottom electrode or directly connected to the top electrode and the bottom electrode respectively. In the manufacturing process for forming the semiconductor device, the via connected to the top electrode, the via connected to the bottom electrode and the via connected to the metal interconnects are simultaneously formed by the same step of etching process. Nevertheless, the depths of the aforementioned three kinds of vias are different and the difficulty level for performing such etching process is enhanced. Hence, some etching problems happen, such as the relatively deep via opening is failed to be opened or the relatively shallow via opening over the top electrode is over-etched to penetrate through the top electrode.

### SUMMARY OF THE INVENTION

Accordingly, at least one objective of the present invention is to provide a method for forming a semiconductor device capable of integrating the process for forming the capacitor and the process for forming the metal interconnects in order to simplify the manufacturing steps.

At least another objective of the present invention is to provide a semiconductor device capable of routing the top electrode layer through the wire underneath thereof. Hence, no via is disposed over the top electrode layer for being connected to the top electrode layer.

Furthermore, the present invention is to provide a method for forming a semiconductor device. Since the via over the wire connected to the top electrode layer has the depth similar to that of the via connected to the bottom electrode, the etching problem due to uneven depths of the vias can be overcome and the process steps are simplified.

To achieve these and other advantages and in accordance with the purpose of the invention, as embodied and broadly described herein, the invention provides a capacitor, comprising a substrate, a first electrode and a second electrode. The first electrode is located over a substrate. The second electrode is located over the first electrode and overlapping with a portion of the first electrode. The dielectric layer is located between the first electrode and the second electrode and a portion of the first electrode, a portion of the dielectric layer and a portion of the second electrode, which overlap each other, are together form the capacitor. The first electrode is electrically connected to a first metal interconnects, the second electrode is electrically connected to a second metal interconnects underneath the second electrode and no via for being electrically connected to the second electrode is located over the second electrode.

According to one embodiment of the present invention, the first metal interconnects comprises at least a first via located on a region of the first electrode without overlapping with the second electrode.

According to one embodiment of the present invention, the first metal interconnects comprises a wire located between the second electrode and the substrate and at a level as same as that of the first electrode and electrically insulated from the first electrode. Also, the second metal interconnects comprises at least a second via located on the wire.

The invention also provides a semiconductor device. The semiconductor device comprises a dielectric layer, a first conductive layer, a second conductive layer, at least a first via and at least a second via. The first conductive layer is located under the dielectric layer and having a first region and a second region separated and electrically insulated from the first region. The second region of the first conductive layer overlaps a portion of the dielectric layer. The second conductive layer is located on a portion of the first region of the first conductive layer and in contact with the first conductive layer and extended onto the dielectric layer so as to overlap a portion of the second region of the first conductive layer. A portion of the first conductive layer, a portion of the dielectric layer and a portion of the second conductive layer, which overlap each other, together form a capacitor. The first via is located on a portion of the first region without being contact with the second conductive layer and electrically connected to the first conductive layer. The second via is located on a portion of the second region without being overlapped by the second conductive layer and electrically connected to the first conductive layer and no via for being connected to the second conductive layer is formed on the second conductive layer.

According to one embodiment of the present invention, the first conductive layer is a metal layer of a plurality of layers from a bottom level metal layer to a top level metal layer.

According to one embodiment of the present invention, the second conductive layer is a metal layer of a plurality of layers from a bottom level metal layer to a bond pad.

According to one embodiment of the present invention, the material of the second conductive layer includes tantalum nitride, and titanium nitride.

According to one embodiment of the present invention, the material of the dielectric layer includes ultraviolet-type silicon nitride and a layer of oxide/nitride/oxide stacked structure.

According to one embodiment of the present invention, the semiconductor device further comprises a cap layer covering the second region of the first conductive layer and extending onto the second conductive layer. The material of the dielectric layer is as same as the material of the cap layer.

The invention further provides a method for forming a semiconductor device. The method comprises forming a first conductive layer over a substrate. The first conductive layer has a first region and a second region and the first region and the second region are separated and electrically isolated from each other. A dielectric layer is formed on a portion of the second region of the first conductive layer. A second conductive layer is formed over the substrate so that the second conductive layer is in contact with a portion of the first region of the first conductive layer and covers a portion of the dielectric layer and a portion of the second region of the first conductive layer. A portion of the first conductive layer, a portion of the dielectric layer and a portion of the second conductive layer, which overlap each other, together form a capacitor. An insulating layer is formed over the substrate. At least a first via is formed in the insulating layer and located on a portion of the first region of the first conductive layer without being in contact with the second conductive layer and electrically connected to the first conductive layer, and at least a second via is formed in the insulating layer and located on a portion of the second region of the first conductive layer without being overlapped with the dielectric layer and electrically connected to the first conductive layer. No via connected to the second conductive layer is formed on the second conductive layer.

According to one embodiment of the present invention, the first conductive layer is a metal layer of a plurality of layers from a bottom level metal layer to a top level metal layer.

According to one embodiment of the present invention, the second conductive layer is a metal layer of a plurality of layers from a bottom level metal layer to a bond pad.

According to one embodiment of the present invention, the material of the second conductive layer includes tantalum nitride, and titanium nitride.

According to one embodiment of the present invention, the material of the dielectric layer includes ultraviolet-type silicon nitride and a layer of oxide/nitride/oxide stacked structure.

According to one embodiment of the present invention, the method further comprises forming a cap layer to cover the second region of the first conductive layer and to extend onto the second conductive layer. The material of the dielectric layer is as same as the material of the cap layer.

The present invention provides a method for forming the semiconductor device in which the process for forming the capacitor is integrated with the process for forming the metal interconnects so that the manufacturing steps are simplified.

The present invention provides a semiconductor device in which the top electrode is routed through the wire underneath the top electrode so that no via is disposed over the top electrode layer for being connected to the top electrode layer.

The present invention provides a method for forming a semiconductor device. Since the via over the wire connected to the top electrode layer has the depth similar to that of the via connected to the bottom electrode, the etching problem due to uneven depths of the vias can be overcome and the process steps are simplified.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1D are top views showing a method for forming a semiconductor device according to one embodiment of the present invention.

FIGS. 2A through 2E are cross-sectional views of FIGS. 1A through 1D along line I-I showing a method for forming a semiconductor device according to one embodiment of the present invention.

### DESCRIPTION OF EMBODIMENTS

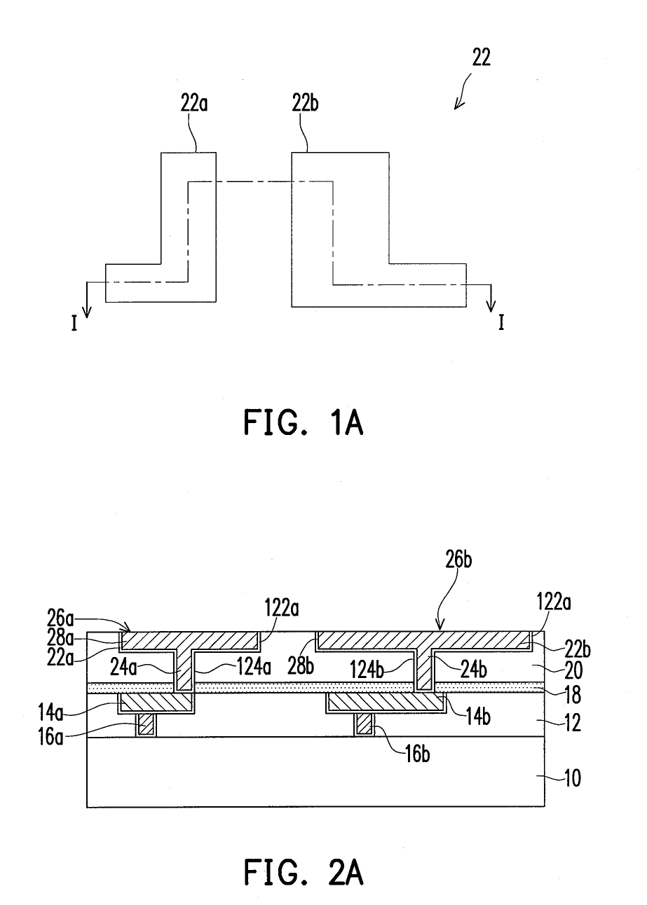

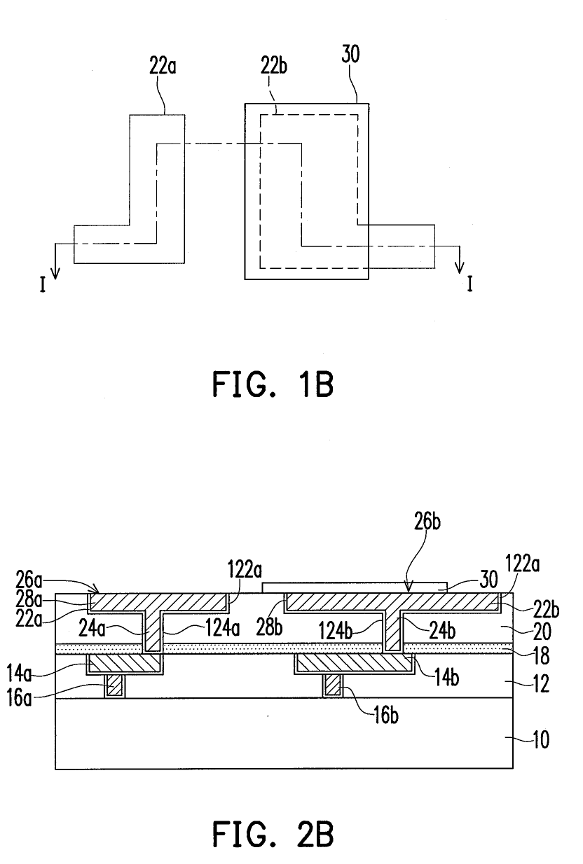

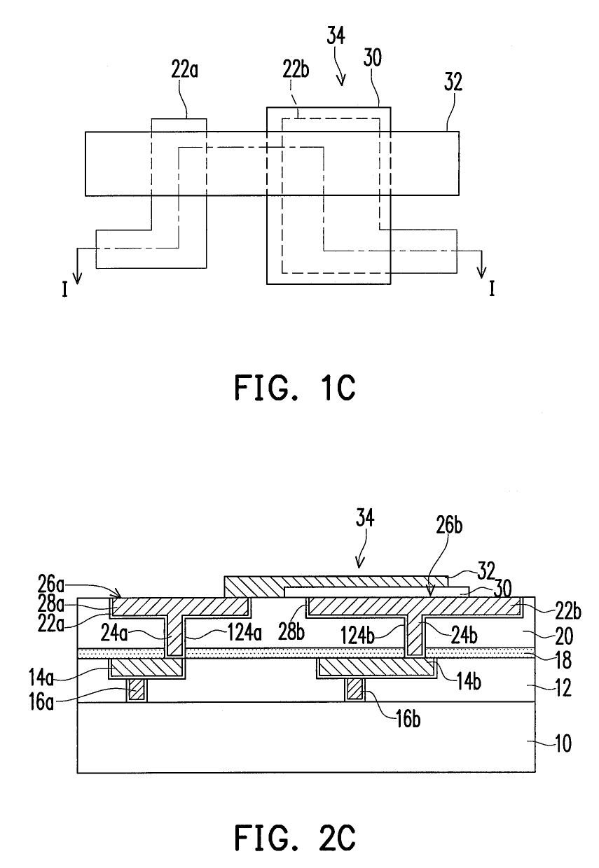

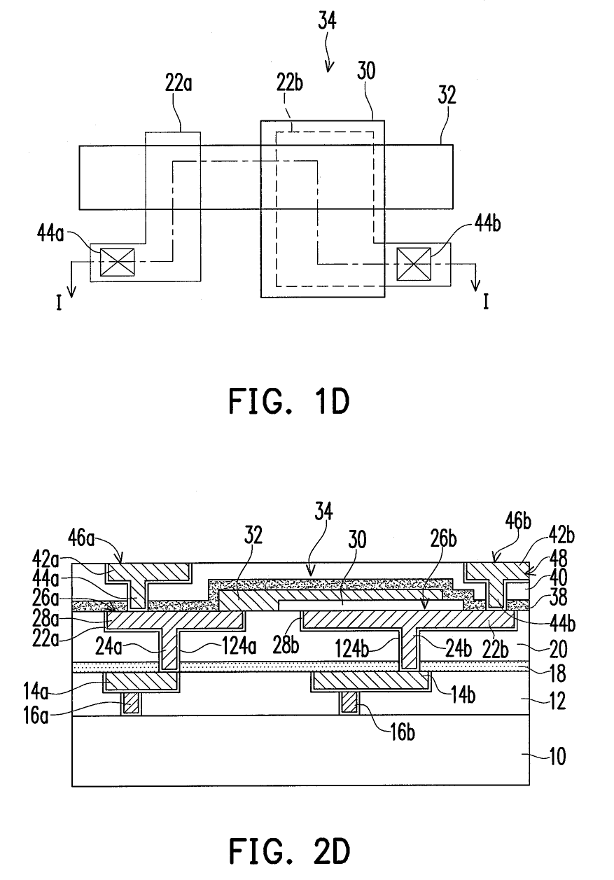

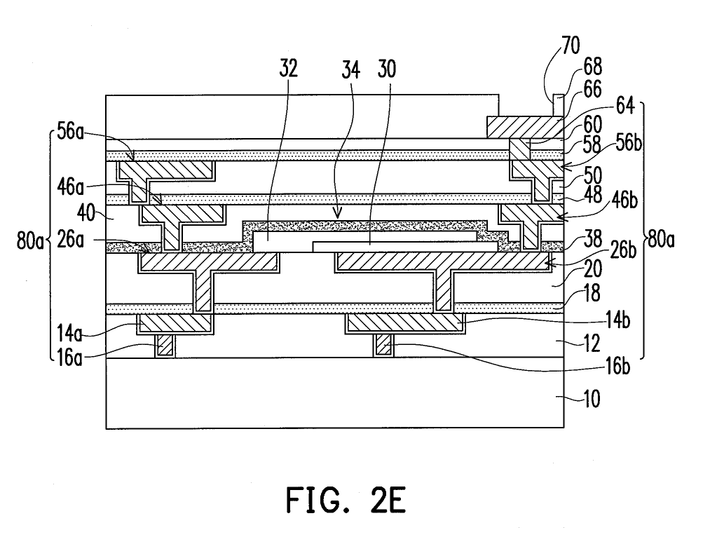

FIGS. 1A through 1D are top views showing a method for forming a semiconductor device according to one embodiment of the present invention. FIGS. 2A through 2E are cross-sectional views of FIGS. 1A through 1D along line I-I showing a method for forming a semiconductor device according to one embodiment of the present invention.

As shown in FIG. 1A and FIG. 2A, a substrate 10 is provided. The substrate 10 cam be, for example but not limited to, a semiconductor substrate 10 such as silicon substrate. The substrate 10 can have metal-oxide-semiconductor transistor formed thereon. Furthermore, an insulating layer 12 is formed over the substrate 10 and there are wires 14a and 14b and contact windows 16a and 16b formed within the insulating layer 12. The material of the insulating layer 12 can be, for example, silicon oxide, fluorosilicate glass (FSG), phosphosilicate glass (PSG) or Borophosphosilicate Glass (BPSG). The method for forming the insulating layer 12 can be, for example, the chemical vapor deposition (CVD). The material of the wires 14a and 14b can be, for example, metal such as aluminum, copper or alloy of aluminum and copper. The wires 14a and 14b can be regarded as a first level of conductive layer (first metal layer). Then, an insulating layer 20 is formed over the substrate 10. The material of the insulating layer 20 and the method for forming the insulating layer 20 are as same as the material and the method mentioned above and are not described herein. Before the insulating layer 20 is formed, a cap layer 18 can be formed over the substrate 10. The material of the cap layer 18 can be as same as or different from that of a later formed dielectric layer 30 (as shown in FIG. 1B and FIG. 2B). The cap layer 18 can be, for example but not limited to, made of an ultraviolet-type silicon nitride or a layer with the oxide/nitride/oxide stacked structure. The method for forming the cap layer 18 can be, for example, CVD, thermal oxidation or the combination thereof.

Thereafter, dual damascene structures 26a and 26b are formed in the insulating layer 20 and the cap layer 18. The dual damascene structure 26a comprises a wire 22a and a via 24a. The dual damascene structure 26b comprises an electrode layer 22b and a via 24b. The height of the wire 22a is approximately equal to that of the electrode layer 22b. Alternatively, both of the wire 22a and the electrode layer 22b are a part of the second level of conductive layer (the second metal layer) 22 in the metal interconnects. Further, the wire 22a is a first region of the second conductive layer 22 and the electrode layer 22b is a second region of the second conductive layer 22 and the first region and the second region are electrically insulated from each other. The method for forming the dual damascene structures 26a and 26b includes forming a trench 122a, a via opening 124a, a trench 122b and a via opening 124b, communicating with the trench 122b, in the insulating layer 20 and the cap layer 18 in advance and then forming a conductive material (not shown) on the insulating layer 20 to fill up the trenches 122a and 122b and the via openings 124a and 124b. The conductive material can be, for example, made of metal copper or copper alloy. Before the conductive layer is formed, a barrier layer can be formed. The barrier layer can be, for example, made of tantalum, titanium, tantalum nitride, titanium nitride or the combination thereof. Then, the conductive material and the barrier layer above the insulating layer 20 are removed so that the dual damascene structures 26a and 26b with the barrier layers 28a and 28b remain. The method for removing the conductive material above the insulating layer 20 can be, for example, the chemical mechanical polishing process.

As shown in FIG. 1B and FIG. 2B, a dielectric layer 30 is formed on the conductive layer 22 so as to at least cover a portion of the electrode layer 22b. The dielectric layer 30 can be, for example but not limited to, made of an ultraviolet-type silicon nitride or a layer with the oxide/nitride/oxide stacked structure. The method for forming the dielectric layer 30 can be, for example, CVD, thermal oxidation or the combination thereof.

As shown in FIG. 1C and FIG. 2C, an electrode layer 32 is formed over the substrate 10. The material of the electrode layer 32 can be, for example, tantalum nitride, or titanium nitride. The electrode layer 32 is connected to a portion of the wire 22a and the electrode layer 32 covers a portion of the dielectric layer 30 and overlaps a portion of the electrode layer 22b. The portion of the electrode layer 22b, the portion of the dielectric layer 30 and the portion of the electrode layer 32, which are overlapped with each other, are together form a capacitor 34. In this embodiment, since the electrode layer 22b is located at a relatively low level and relatively close to the substrate 10, the electrode layer 22b is regarded as the bottom electrode. Furthermore, the electrode layer 32 is located at a relatively high level and more away from the substrate 10 so that the electrode layer 32 is regarded as the top electrode.

As shown in FIG. 1D and FIG. 2D, an insulating layer 40 is formed over the substrate 10 so as to cover the electrode layer 32, the dielectric layer 30 and the wires 22a and 22b. Before the insulating layer 40 is formed, a cap layer 38 can be formed over the substrate 10 to cover the wire 22a and the electrode layer 22b and further cover the electrode layer 32 in order to protect the electrode layer 32. The material of the cap layer 38 is different from that of the insulating layer 40 and the cap layer 38 can be used as an etching stop layer in the etching process in a later performed process for forming the dual damascene structure. The cap layer 38 can be made of the material as same as or different from that of the dielectric layer 30. The cap layer 38 can be, for example but not limited to, made of an ultraviolet-type silicon nitride or a layer with the oxide/nitride/oxide stacked structure. The method for forming the cap layer 38 can be, for example, CVD, thermal oxidation or the combination thereof.

Then, dual damascene structures 46a and 46b are formed in the insulating layer 40 and the cap layer 38. The dual damascene structure 46a comprises a wire 42a and a via 44a. Also, the dual damascene structure 46a comprises a wire 42b and a via 44b. The via 44a is located on a region of the wire 22a which is not connected to the electrode layer 32 and the via 44a is electrically connected to the wire 22a. The via 44b is located on a portion of the electrode layer 22b which is not covered by the electrode layer 32 and the via 44b is electrically connected to the electrode layer 22b. The method for forming the dual damascene structures 46a and 46b is similar to that for forming the dual damascene structures 26a and 26b and is not described herein.

It should be noticed that, in the present invention, the electrode layer 32 is routed through the wire 22a underneath so that no via for being electrically connected to the electrode layer 32 is formed on the electrode layer 32 and the vias 44a and 44b formed in the insulating layer 40 and the cap layer 38 are electrically connected to the wires 22a and 22b. Because the depth of the via 44a is approximately equal to that of the via 44b, the problems, such as the relatively deep via opening is failed to be opened or the relatively shallow via opening over the top electrode is over-etched to penetrate through the top electrode, due to uneven depths of the vias in the manufacturing process can be overcome.

As shown in FIG. 1E, dual damascene structures 56a and 56b are formed in a cap layer 48 and an insulating layer 50 over the substrate 10. The method for forming the dual damascene structures 56a and 56b and the materials of the dual damascene structures 56a and 56b are similar to those of the dual damascene structures 26a and 26b and are not described herein. Then, a cap layer 58 and an insulating layer 60 are formed over the substrate 10 and a via 64 is formed in the cap layer 58 and the insulating layer 60. The methods for forming the cap layer 58 and the insulating layer 60 and the materials of the cap layer 58 and the insulating layer 60 is similar to those of the cap layer 18 and the insulating layer 12 and are not described herein. Thereafter, a bond pad 66 is formed on the insulating layer 60 to electrically connected to the via 64. Then, a passivation layer 68 is formed over the substrate 10 and a pad opening 70 is formed in the passivation layer 68 to expose bond pad 66.

In the aforementioned embodiment, a metal interconnects 80a is constructed by the dual damascene structures 56a, 46a and 26a, the wire 14a and the contact window 16a and a metal interconnects 80b is constructed by the via 64, the dual damascene structures 56b, 46b and 26b, the wire 14b and the contact window 16b. The electrode layer 32 is regarded as the top electrode of the capacitor 34 and there is no via formed over the electrode layer 32 for being electrically connected to the electrode layer 32. The electrode layer 32 is routed through the wire 22a underneath. More specifically, the electrode layer 32 is electrically connected to the wire 22a and the voltage is applied onto the electrode layer 32 through the metal interconnects 80a. The electrode layer 22b is regarded as the bottom electrode of the capacitor 34 and the voltage is applied onto the electrode layer 22b through the metal interconnects 80b.

Moreover, the method for forming metal interconnects is described by using the dual damascene process as an example. However, the present invention is not limited to. In the practice, the classical method can be used to manufacture the metal interconnects. On the other words, the wire and the via can be formed by the steps of forming the insulating layer in advance, forming the via in the insulating layer and then forming the wire on the insulating layer to electrically connect to the via and the steps repeat.

In the above embodiment, a portion of the second level of conductive layer (the second metal layer) is used as the bottom electrode of the capacitor and used as the wire for being connected to the top electrode. However, in practice, the present invention is not limited to. The bottom electrode and the wire connected to the top electrode of the present invention can be any level of conductive layer (metal layer) from the bottom level of conductive layer (metal layer) to the top level of conductive layer in the metal interconnects in the manufacturing process of the semiconductor device. The top electrode can be any level of conductive layer from the bottom level of the conductive layer to the bond pad.

Since no via is formed on the top electrode layer to be electrically connected to the top electrode layer and the depth of the via for connecting to bottom electrode is approximately equal to the depth of the via on the wire in contact with the top electrode, the problems, such as the relatively deep via opening is failed to be opened or the relatively shallow via opening over the top electrode is over-etched to penetrate through the top electrode, due to uneven depths of the vias in the manufacturing process can be overcome. Thus, the etching problems due to the uneven depths of the vias can be overcome and the process is simplified.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A capacitor, comprising:
a first electrode located over a substrate;
a second electrode located over the first electrode and overlapping with a portion of the first electrode;
a dielectric layer located between the first electrode and the second electrode, wherein a portion of the first electrode, a portion of the dielectric layer and a portion of the second electrode, which overlap each other, are together form the capacitor and the first electrode is electrically connected to a first metal interconnects, the second electrode is electrically connected to a second metal interconnects underneath the second electrode and no via for being electrically connected to the second electrode is located over the second electrode.

2. The capacitor of claim 1, wherein the first metal interconnects comprises at least a first via located on a region of the first electrode without overlapping with the second electrode.

3. The capacitor of claim 1, wherein the first metal interconnects comprises a wire located between the second electrode and the substrate and at a level as same as that of the first electrode and electrically insulated from the first electrode.

4. The capacitor of claim 3, wherein the second metal interconnects comprises at least a second via located on the wire.

5. A semiconductor device, comprising:
a dielectric layer;
a first conductive layer located under the dielectric layer and having a first region and a second region separated and electrically insulated from the first region, wherein the second region of the first conductive layer overlaps a portion of the dielectric layer;
a second conductive layer located on a portion of the first region of the first conductive layer and in contact with the first conductive layer and extended onto the dielectric layer so as to overlap a portion of the second region of the first conductive layer, wherein a portion of the first conductive layer, a portion of the dielectric layer and a portion of the second conductive layer, which overlap each other, together form a capacitor;
at least a first via located on a portion of the first region without being contact with the second conductive layer and electrically connected to the first conductive layer; and
at least a second via located on a portion of the second region without being overlapped by the second conductive layer and electrically connected to the first conductive layer, wherein no via for being connected to the second conductive layer is formed on the second conductive layer.

6. The semiconductor device of claim 5, wherein the first conductive layer is a metal layer of a plurality of layers from a bottom level metal layer to a top level metal layer.

7. The semiconductor device of claim 5, wherein the second conductive layer is a metal layer of a plurality of layers from a bottom level metal layer to a bond pad.

8. The semiconductor device of claim 5, wherein the material of the second conductive layer includes tantalum nitride, and titanium nitride.

9. The semiconductor device of claim 5, wherein the material of the dielectric layer includes ultraviolet-type silicon nitride and a layer of oxide/nitride/oxide stacked structure.

10. The semiconductor device of claim 5 further comprising a cap layer covering the second region of the first conductive layer and extending onto the second conductive layer.

11. The semiconductor device of claim 10, wherein the material of the dielectric layer is as same as the material of the cap layer.

12. A method for forming a semiconductor device, comprising:
forming a first conductive layer over a substrate, wherein the first conductive layer has a first region and a second region and the first region and the second region are separated and electrically isolated from each other;
forming a dielectric layer on a portion of the second region of the first conductive layer;
forming a second conductive layer over the substrate so that the second conductive layer is in contact with a portion of the first region of the first conductive layer and covers a portion of the dielectric layer and a portion of the second region of the first conductive layer, wherein a portion of the first conductive layer, a portion of the dielectric layer and a portion of the second conductive layer, which overlap each other, together form a capacitor;
forming an insulating layer over the substrate;
forming at least a first via in the insulating layer, located on a portion of the first region of the first conductive layer without being in contact with the second conductive layer and electrically connected to the first conductive layer, and forming at least a second via in the insulating layer, located on a portion of the second region of the first conductive layer without being overlapped with the dielectric layer and electrically connected to the first conductive layer, wherein no via connected to the second conductive layer is formed on the second conductive layer.

13. The method of claim 12, wherein the first conductive layer is a metal layer of a plurality of layers from a bottom level metal layer to a top level metal layer.

14. The method of claim 12, wherein the second conductive layer is a metal layer of a plurality of layers from a bottom level metal layer to a bond pad.

15. The method of claim 12, wherein the material of the second conductive layer includes tantalum nitride, and titanium nitride.

16. The method of claim 12, wherein the material of the dielectric layer includes ultraviolet-type silicon nitride and a layer of oxide/nitride/oxide stacked structure.

17. The method of claim 12, further comprising forming a cap layer to cover the second region of the first conductive layer and to extend onto the second conductive layer.

18. The method of claim 17, wherein the material of the dielectric layer is as same as the material of the cap layer.
